(19) United States
(12) Patent Application Publication
(10) Pub. No.: US 2012/0153950 A1
(43) Pub. Date: Jun. 21, 2012

(54) RF SHIMMED MRI SLICE EXCITATION ALONG A CURVED SPOKE K-SPACE TRAJECTORY

(75) Inventor: Ulrich Katscher, Norderstedt (DE)

(73) Assignee: KONINKLIJKE PHILIPS ELECTRONICS N.V., EINDHOVEN (NL)

(21) Appl. No.: 13/390,618

(22) PCT Filed: Aug. 5, 2010
(86) PCT No.: PCT/IB10/53550

§ 371 Date: Feb. 15, 2012

Related U.S. Application Data
(60) Provisional application No. 61/240,415, filed on Sep. 8, 2009.

(51) Int. Cl. G01R 33/44

(52) U.S. Cl. 324/307; 324/318

(57) ABSTRACT

A radio-frequency (RF) shimming apparatus (50) for use in a magnetic resonance imaging (MRI) system (10) comprises of a spatial sensitivity unit (30) which determines a transmit spatial sensitivity distribution of at least one RF coil (18,18′). A selection unit (32) selects an excitation pattern with a through-plane, one-dimensional excitation k-space trajectory. The through-plane, one-dimensional excitation k-space trajectory is curved into at least a second dimension by an optimization unit (34) according to the generated spatial sensitivity distribution. The optimization unit (34) supplies the curved excitation k-space trajectory to at least one transmitter (24) which causes the at least one RF transmit coil (18,18′) to transmit the selected excitation pattern with the curved excitation k-space trajectory.

The present application relates to the magnetic resonance arts. It finds particular application in conjunction with radio-frequency (RF) shimming of parallel transmit systems. It is to be appreciated, however, that the present application will also find application in conjunction with other types of magnetic resonance imaging, spectroscopy, and other diagnostic techniques which use radio frequency coils.

Magnetic resonance imaging (MRI) and spectroscopy (MRS) systems are often used for the examination and treatment of patients. By such a system, the nuclear spins of the body tissue to be examined are aligned by a static main magnetic field B₀ and are excited by transverse magnetic fields B₁ oscillating in the radiofrequency band. In imaging, relaxation signals are exposed to gradient magnetic fields to localize the resultant resonance. The relaxation signals are received in order to form in a known manner a single or multi-dimensional image. In spectroscopy, information about the composition of the tissue is carried in the frequency component of the resonance signals.

Two types of MR systems that are in common use include “open” MR systems (vertical system) and “bore-type” systems. In the former, the patient is introduced into an examination zone which is situated between two magnetic poles connected by a C-shaped unit. The patient is accessible during the examination or treatment from practically all sides. The latter comprises a cylindrical examination space (axial system) into which a patient is introduced.

An RF coil system provides the transmission of RF signals and the reception of resonance signals. In addition to the RF coil system which is permanently built into the imaging apparatus, special purpose coils can be flexibly arranged around or in a specific region to be examined Special purpose coils are designed to optimize signal-to-noise ratio (SNR), particularly in situations where homogeneous excitation and high sensitivity detection is required. Furthermore, special sequences of RF signals, higher field strengths, high flip angles or real-time sequences can be realized and generated by multi-channel antenna arrangements, and multi-dimensional excitations can be accelerated.

MR imaging and spectroscopy benefit from improved signal-to-noise (SNR) ratios and contrast-to-noise ratios (CNR) at higher static magnetic field strengths, for example greater than 3 Tesla (T), because a larger number of the protons align along the main magnetic field and thus increase longitudinal magnetization and increase precession rates. Nonetheless, wave propagation effects diminish SNR and CNR at main field strengths of about 3 T and above. One such factor in this reduction is B₁ field inhomogeneities which cause non-uniform SNR and CNR across the imaging volume. Conductive loading of patient tissue coupled with dielectric resonances created by objects longer than the transmit wavelength results in the B₁ field inhomogeneities.

Effective methods have been developed to mitigate B₁ field inhomogeneities such as adiabatic pulses, novel coil designs, and image processing techniques. However, adiabatic pulses suffer from high SAR absorption, coil designs cannot account for the subject's shape and size, and image processing techniques merely normalize pixel intensities which do not improve SNR or CNR.

Parallel RF transmission systems have the potential of compensating for B₁ field inhomogeneities through RF shimming RF shimming can be performed in two different ways. Basic RF shimming adjusts the global amplitude and phase of the currents in each independent transmit element, aiming at a constant B₁ in the region of interest. Basic RF shimming applies standard slice selective RF pulses, typically with a sinc shape, corresponding to a one-dimensional (through-plane) trajectory in the excitation k-space. By adjusting the global amplitude and phase of the currents in each transmit element, one can achieve a relatively constant B₁ amplitude in the region of interest in many situations. For 3D volume imaging, 3D RF shimming is facilitated using different frequencies for the deferent transmit elements. The elements of a transmit array are driven with different frequencies to excite different slabs in the excitation volume via the underlying gradient. Amplitudes and phases can be optimized for each slab individually to achieve optimal homogeneity. The advantage of basic RF shimming is that it can be easily combined with nearly every MR sequence, since basic RF shimming does not require any change of sequence timing or sequence gradients. On the other hand, basic RF shimming is of limited flexibility, i.e., not all B₁ signal inhomogeneities can be compensated, particularly when using only two RF transmit channels.

Tailored RF shimming can be performed via multi-dimensional RF pulses designed to achieve a spatially constant excitation pattern. Typically, a two-dimensional, in-plane trajectory in the excitation k-space is used, which allows the excitation of an arbitrary spatial magnetization pattern. Moreover, additional dimensions might be taken into account, like through-plane or spectral dimension. Multi-dimensional RF pulses do not require parallel transmission; however, parallel transmission allows the acceleration of multi-dimensional RF pulses with Transmit SENSE or alternative techniques. Assuming a sufficient pulse length, nearly all B₁ signal inhomogeneities can be compensated. Although tailored RF shimming has a very high RF shimming potential, it has a big impact on sequence timing and sequence gradients. Even with acceleration techniques, multi-dimensional RF pulses are typically much longer than standard 1D sinc pulses.

The present application provides a new and improved radio-frequency shimming apparatus and method which overcomes the above-referenced problems and others.

In accordance with one aspect, a radio-frequency (RF) shimming apparatus is comprised of a spatial sensitivity unit which determines a transmit spatial sensitivity distribution of at least one RF coil. A selection unit selects an excitation pattern with an excitation k-space trajectory. An optimization unit curves the excitation k-space trajectory of the selected excitation pattern according to the generated spatial sensitivity distribution, and supplies the curved excitation k-space trajectory to at least one transmitter which causes the at least one RF transmit coil to transmit the selected excitation pattern with the curved excitation k-space trajectory.

In accordance with another aspect, a method for radio-frequency shimming is comprised of determining a transmission spatial sensitivity distribution of at least one RF transmit coil, and selecting an excitation pattern with an excitation k-space trajectory. The excitation k-space trajectory of the selected excitation pattern is curved according to the generated spatial sensitivity distribution. At least one transmitter is controlled to cause the at least one RF coil to transmit the selected excitation pattern with the curved excitation k-space trajectory.

One advantage resides in that homogeneity of a B1 excitation field is improved.

Another advantage resides in reduced specific absorption rate (SAR) hot spots.

Another advantage resides in improved signal-to-noise ratio (SNR) and contrast-to-noise ratio (CNR).

Another advantage resides in improved acquisition times.

Another advantage resides in enabling standard MR sequences notwithstanding improved RF shimming.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

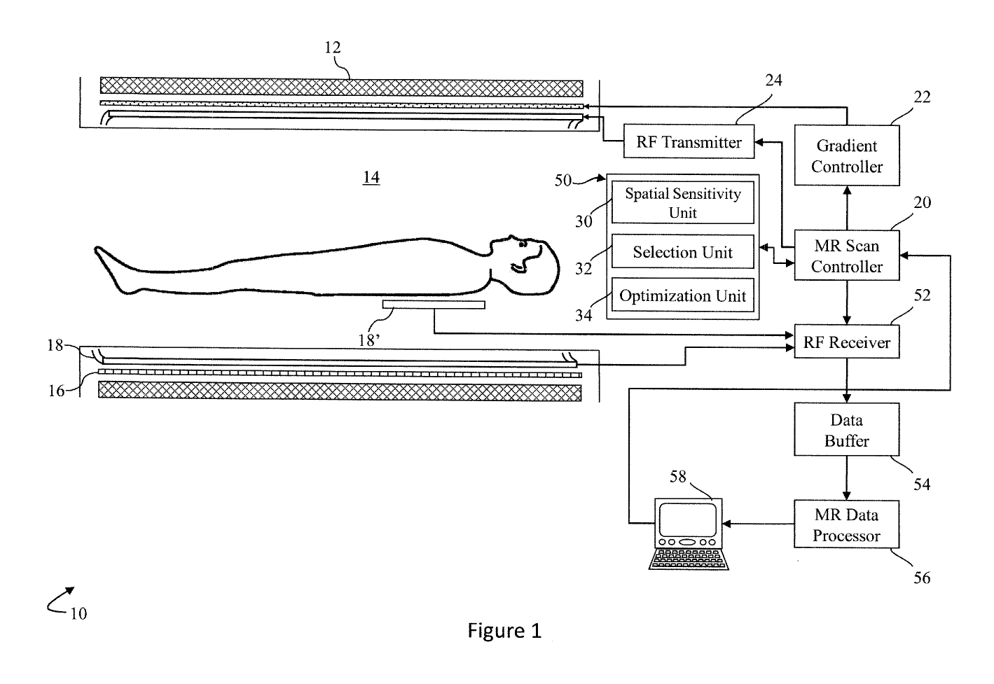

FIG. 1 diagrammatically shows a magnetic resonance system employing an RF shimming apparatus;

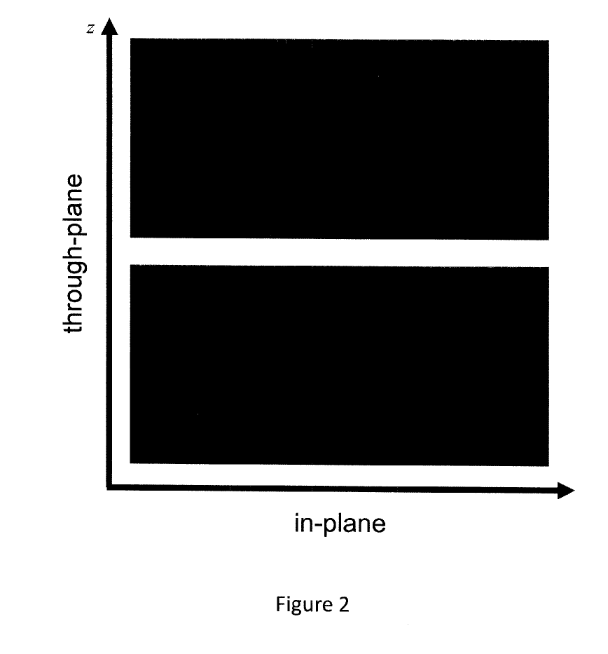

FIG. 2 illustrates a targeted spatial sensitivity distribution; and

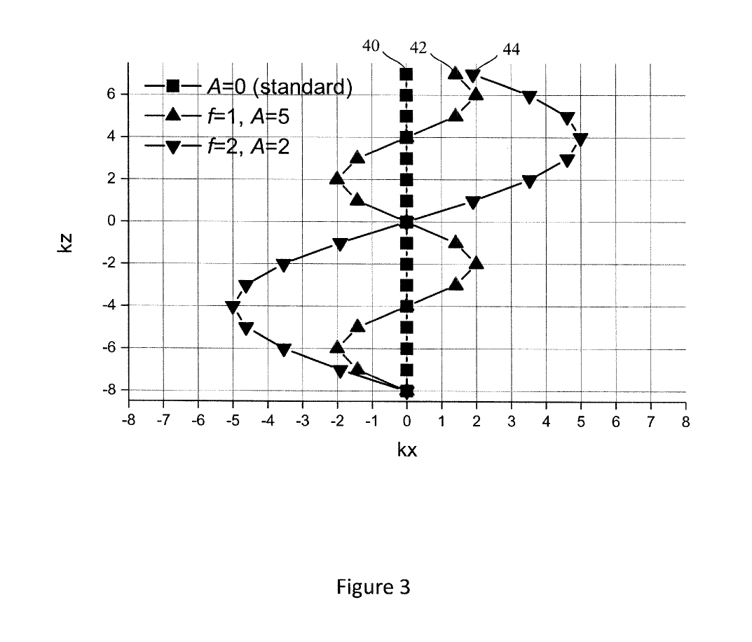

FIG. 3 illustrates a slice-selective, one-dimensional RF spoke trajectory and examples of curved spoke trajectories;

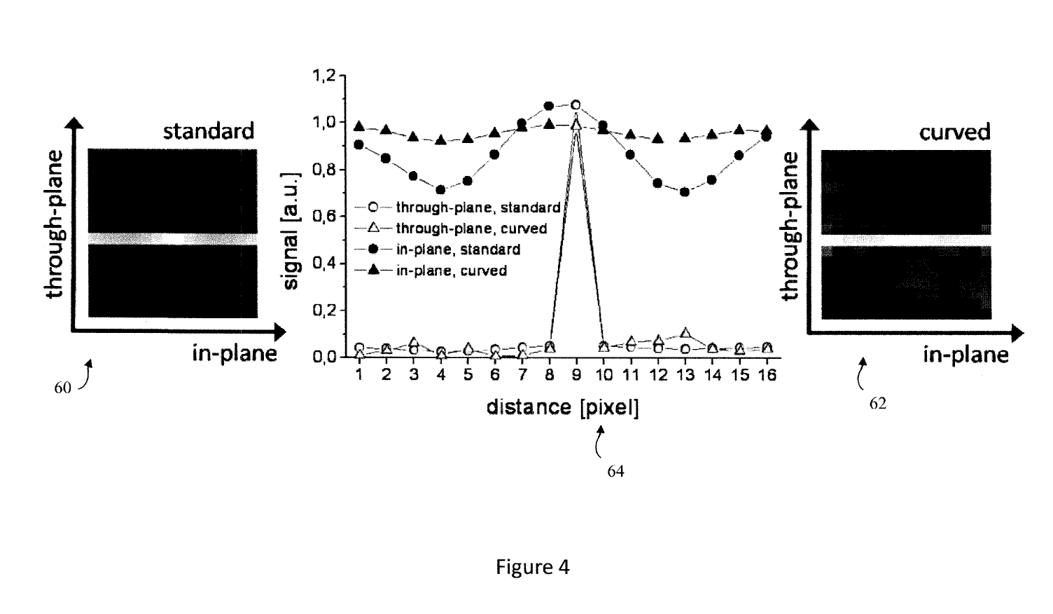

FIG. 4 illustrates simulation excitation results for basic RF shimming (left), curved spoke shimming (right), and in-plane and through-plane profiles (middle); and

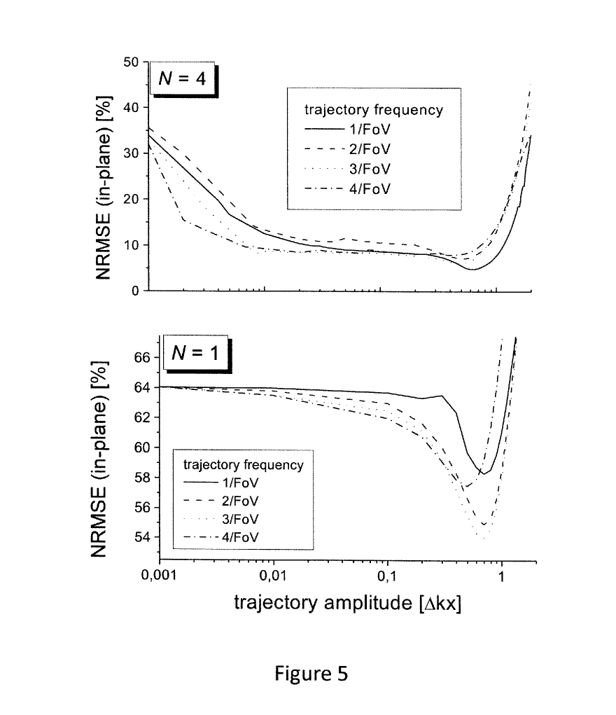

FIG. 5 illustrates the in-plane normalized root-mean-square error (NRMSE) as a function of amplitude A and frequency f of the curved trajectory where N is the number of transmit elements.

With reference to FIG. 1, a magnetic resonance (MR) imaging system 10 includes a main magnet 12 which generates a temporally uniform B₀ field through an examination region 14. The main magnet can be an annular or bore-type magnet, a C-shaped open magnet, other designs of open magnets, or the like. Gradient magnetic field coils 16 disposed adjacent the main magnet serve to generate magnetic field gradients along selected axes relative to the B₀ magnetic field for spatially encoding magnetic resonance signals, for producing magnetization-spoiling field gradients, or the like. The magnetic field gradient coil 16 may include coil segments configured to produce magnetic field gradients in three orthogonal directions, typically longitudinal or z, transverse or x, and vertical or y directions.

A radio-frequency (RF) coil assembly 18, such as a whole-body radio frequency coil, is disposed adjacent the examination region. The RF coil assembly generates radio frequency pulses for exciting magnetic resonance in aligned dipoles of the subject. The radio frequency coil assembly 18 also serves to detect magnetic resonance signals emanating from the imaging region. Optionally, local, surface or in vivo RF coils 18′ are provided in addition to or instead of the whole-body RF coil 18 for more sensitive, localized spatial encoding, excitation, and reception of magnetic resonance signals. The whole body coil can comprise of a single coil or a plurality of coil elements of an array as in a parallel transmit system. In parallel transmit systems, the k-space trajectory can be configured for a specific spatial sensitivity which ultimately shortens the overall pulse length. In one embodiment, the k-space trajectory determined by the gradient system, i.e. the gradient coil 16 and gradient controller 22, is the same for all transmit coils. In another embodiment, different B₁ pulses are determined individually for each transmit element of the transmit coil (18,18′) array.

To acquire magnetic resonance data of a subject, the subject is placed inside the examination region 14, preferably at or near an isocenter of the main magnetic field. A scan controller 20 controls a gradient controller 22 which causes the gradient coils to apply the selected magnetic field gradient pulses across the imaging region, as may be appropriate to a selected magnetic resonance imaging or spectroscopy sequence. The scan controller 20 also controls at least one RF transmitter 24 which causes the RF coil assembly to generate magnetic resonance excitation and manipulation of B₁ pulses. In a parallel system, the RF transmitter 24 includes a plurality of transmitters or a single transmitter with a plurality of transmit channels, each transmit channel operatively connected to a corresponding coil element of the array. To improve homogeneity of the B₁ pulses in the examination region 14, a spatial sensitivity distribution of the transmit coils 18, 18′ are determined by a spatial sensitivity unit 30, e.g. by a short measurement prior to the actual imaging sequence to compensate for dielectric resonances occurring in patient tissue at high frequencies, i.e. Larmor frequency at static fields strengths of 3 T or greater.

After the spatial sensitivity distribution is determined, an excitation pattern with an excitation k-space trajectory is selected by a selection unit 32. The excitation k-space trajectory typically includes of a single spoke or a one-dimensional, slice-selective straight line in the through-plane direction kz as shown in FIG. 3, though multi-spoke trajectories are also contemplated. Typically, the excitation pattern is adapted to the individual imaging protocol; however, an excitation pattern can be selected from a number of pre-determined excitation patterns stored in a memory of the selection unit 32 by an operator or automatically selected by the selection unit.

In a next step, an optimization unit 34 determines RF pulses for the individual transmit channels based on the selected excitation pattern, the corresponding excitation k-space trajectory, and the determined spatial sensitivity distribution. The RF pulses can be determined using known techniques such as Transmit SENSE or the like. The optimization unit 34 utilizes the determined RF pulses to optimize the through-plane spoke of the excitation k-space trajectory by curving the spoke in the in-plane direction(s) kx or ky. With reference to FIG. 3, a standard slice-selective, one dimensional trajectory or spoke 40 is illustrated with two curved trajectories 42, 44 that are curved in the kx direction. The trajectories kx versus kz are curved according a sine curve defined by:

kx=A sin(2πfkz/kₘₐₓ+ψ) equation 1

where A is an amplitude, kₘₐₓ is a maximum of a k-space range, f is a frequency of the sine function in the through-plane direction, kz is a running variable in k-space in the z-direction, and ψ is a phase of the sine function. The amplitude A, frequency f, and phase ψ of the curved excitation k-space trajectory in one embodiment are iteratively varied to find the optimal curvature. Alternatively, optimization algorithms such as simulated annealing, conjugate gradients, or the like can be employed to determine the optimal curvature. Alternatively, a look-up table can be employed to match several curved trajectories stored in a memory in the optimization unit 34 to the corresponding determined RF pulses.

With returning reference to FIG. 1, the scan controller 20 receives the curved excitation k-space trajectories from the RF shimming apparatus 50, comprising of the spatial sensitivity unit 30, the selection unit 32, and the optimization unit 34, and provides curved excitation k-space trajectories to the RF transmitter(s) and the transmit coils 18, 18′. As a result, the homogeneity of the overall B₁ field is substantially improved at higher field strengths. The scan controller also controls an RF receiver 52 which is connected to the RF coil assembly to receive the generated magnetic resonance signals therefrom. The received data from the receiver 52 is temporarily stored in a data buffer 54 and processed by a magnetic resonance data processor 56. The magnetic resonance data processor can perform various functions as are known in the art, including image reconstruction (MRI), magnetic resonance spectroscopy (MRS), catheter or interventional instrument localization, and the like. Reconstructed magnetic resonance images, spectroscopy readouts, interventional instrument location information, and other processed MR data are stored in memory, such as a medical facility's patient archive. A graphic user interface or display device 58 includes a user input device which a clinician can use for controlling the scan controller 20 to select scanning sequences and protocols, display MR data, and the like.

With reference to FIG. 4, results of simulated excitation are illustrated for standard basic RF shimming 60 and curved spoke shimming 62 with a curved k-space excitation trajectory (f=0.9/FoV, A=0.4Δkx, and ψ=8°). In the graph 64, corresponding in-plane and through-plane profiles show that using curved spokes improve the in-plane homogeneity while maintaining through-plane slice-profile. In parallel systems with four transmit elements, simulations have shown a normalized root-mean-square error (NRMSE) of 38.8% for basic shimming which can be reduced to an NRMSE of 3.2% using a curved excitation k-space trajectory as proposed. For single channel systems, the resulting NRMSE for curved spoke shimming was 53.7% (f=0.35/FoV, A=0.72Δkx, and ψ=10°) versus 64.1% for the basic shimming With reference to FIG. 5, the in-plane NRMSE as a function of amplitude A and frequency f of the curved trajectory where N is the number of transmit elements is illustrated. Basic shimming, where A=0, is not visible due to logarithmic scaling.

With reference to FIGS. 2-5, the illustrated embodiment corresponds to curving the excitation k-space trajectory in a single direction, i.e. the x-direction, for a one-dimensional imaging plane, but a curve in the y-direction is also contemplated. In another embodiment, the MR sequence is applied to two-dimensional imaging planes, e.g. the x-direction and y-direction, in which the excitation k-space trajectory is curved in both of the corresponding directions defined by:

kx=A sin(2πfkz/kₘₐₓ+ψ)cos(φ_{twist}kz/kₘₐₓ+φ_{off}) equation 2

ky=A sin(2πfkz/kₘₐₓ+ψ)sin(φ_{twist}kz/kₘₐₓ+φ_{off}) equation 3

where additional parameters φ_{twist} is a magnitude of the twist and φ_{off} is a offset of the trajectory's twist. The result is a twist of the excitation k-space trajectory about the central axis kx=ky=0. It should also be appreciated that different parameterizations of curved trajectories are also contemplated. For example, alternatives to equation 1 are defined by:

kx=a₀(kz−a₁)exp(−(kz−a₂)²/a₃) equation 4

kx=b₀(kz−b₁)(kz−b₂)(kz−b₃) equation 5

where constants a₀, a₁, a₂, a₃ and b₀, b₁, b₂, b₃ are optimized individually.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A radio-frequency (RF) shimming apparatus, comprising:
a spatial sensitivity unit which determines a transmit spatial sensitivity distribution of at least one RF coil;
a selection unit which selects an excitation pattern with an excitation k-space trajectory;
an optimization unit which curves the excitation k-space trajectory of the selected excitation pattern according to the generated spatial sensitivity distribution, and supplies the curved excitation k-space trajectory to the gradient system via the gradient controller and the RF pulses to at least one transmitter which causes the at least one RF transmit coil to transmit the selected excitation pattern with the curved excitation k-space trajectory.

2. The RF shimming apparatus according to claim 1, wherein the excitation k-space trajectory prior to optimization includes at least one slice selective, single-dimension spoke.

3. The RF shimming apparatus according to claim 1, wherein the optimization unit curves the excitation k-space trajectory according to a sine function:
kz=A sin(2πfkz/kₘₐₓ+ψ)
where A is an amplitude, kₘₐₓ is a maximum of a k-space range, f is a frequency of the sine function, and ψ is a phase of the sine function.

4. The RF shimming apparatus according to claim 1, wherein the optimization unit curves the excitation k-space trajectory according to a sine functions:
kx=A sin(2πfkz/kₘₐₓ+ψ)cos(φ_{twist}kz/kₘₐₓ+φ_{off})
ky=A sin(2πfkz/kₘₐₓ+ψ)sin(φ_{twist}kz/kₘₐₓ+φ_{off})
where A is an amplitude, kₘₐₓ is a maximum of a k-space range, f is a frequency of the sine function, ψ is a phase of the sine function, φ_{twist} is a magnitude of a twist, and φ_{off} is an offset of a twist.

5. The RF shimming apparatus according to claim 1, wherein the optimization unit optimizes an amplitude, phase, and frequency of the excitation k-space trajectory based on the generated spatial sensitivity distribution and a selected excitation pattern to curve the excitation k-space trajectory.

6. The RF shimming apparatus according to claim 1, wherein the optimization unit optimizes an amplitude, phase, and frequency of the excitation k-space trajectory based on the generated spatial sensitivity distribution and a selected excitation pattern to curve the excitation k-space trajectory in a direction orthogonal to the trajectory.

7. The RF shimming apparatus according to claim 1, wherein the optimized excitation k-space trajectory is curved according to a sine function.

8. A magnetic resonance system, comprising:
a magnet which generates a static magnetic field in an examination region;
the RF shimming apparatus according to claim 1;
at least one RF coil connected with at least one transmitter which induces and manipulates magnetic resonance by applying RF pulses with the curved excitation k-space trajectory to the examination region; and
an RF coil which receives magnetic resonance data from the examination region.

9. The magnetic resonance system according to claim 8, wherein the magnet generates a static magnetic field of 3 Tesla (T) or above.

10. A radio-frequency shimming method, comprising:
determining a transmission spatial sensitivity distribution of at least one RF transmit coil;
selecting an excitation pattern with an excitation k-space trajectory;
curving the excitation k-space trajectory of the selected excitation pattern according to the generated spatial sensitivity distribution; and
controlling at least one transmitter to cause the at least one RF coil to transmit the selected excitation pattern with the curved excitation k-space trajectory.

11. The method according claim 10, wherein the selected excitation k-space trajectory includes at least one single-dimension spoke.

12. The method according to claim 10, wherein the step of curving curves a plurality of one-dimensional excitation k-space trajectories independently into at least a second dimension.

13. The method according to claim 10, wherein the excitation k-space trajectory is curved according to:
kx=A sin(2πfkz/kₘₐₓ+ψ)
where A is an amplitude, kₘₐₓ is a maximum of the k-space range, f is a frequency of the sine function, and ψ is a phase of the sine function for at least one spoke.

14. The method according to claim 10, wherein the excitation k-space trajectory is curved according to:
kx=A sin(2πfkz/kₘₐₓ+ψ)cos(φ_{twist}kz/kₘₐₓ+φ_{off})
ky=A sin(2πfkz/kₘₐₓ+ψ)sin(φ_{twist}kz/kₘₐₓ+φ_{off})
where A is an amplitude, kₘₐₓ is a maximum of a k-space range, f is a frequency of the sine function, ψ is a phase of the sine function, φ_{twist} is a magnitude of a twist, and φ_{off} is an offset of a twist.

15. The method according to claim 10, further including:
determining an optimal amplitude, phase, and frequency of the curved excitation k-space trajectory based on the generated spatial sensitivity distribution to curve the excitation k-space trajectory.

16. The method according to claim 10, wherein the curving step includes curving the excitation k-space trajectory with a sine function.

17. A processor configured to perform the steps of claim 10.

18. A computer readable medium carrying a computer program which controls a processor to perform the method of claim 10.

19. A magnetic resonance system, comprising:
a magnet which generates a static magnetic field in an examination region;
a processor programmed to perform the method of claim 10;
at least one RF coils connected with the transmitter to induce and manipulate magnetic resonance by applying RF pulses with the optimized excitation k-space trajectory to the examination region; and
the at least one or more RF receive coils also being connected to a receiver which acquires magnetic resonance data from the examination region.
